(19) United States
(12) Patent Application Publication
(10) Pub. No.: US 2010/0078831 A1
(43) Pub. Date: Apr. 1, 2010

(54) INTEGRATED CIRCUIT PACKAGE SYSTEM WITH SINGULATION PROCESS

(76) Inventors: Jairus Legaspi Pisigan, Singapore (SG); Zigmund Ramirez Camacho, Singapore (SG); Henry Descalzo Bathan, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/239,707

(22) Filed: Sep. 26, 2008

(51) Int. Cl. H01L 23/28; H01L 21/00

(52) U.S. Cl. 257/787; 438/124; 257/E21.499

(57) ABSTRACT

An integrated circuit package system includes: providing a die attach pad; forming a package contact pad adjacent the die attach pad; attaching an integrated circuit over the die attach pad; attaching a die connector to the integrated circuit and the package contact pad; and forming an encapsulant over the die connector and the integrated circuit, the encapsulant having an encapsulant edge from a sawless singulation process.

### TECHNICAL FIELD

The present invention relates generally to integrated circuit package systems and more particularly to a system for integrated circuit package with singulation process.

### BACKGROUND ART

Integrated circuit devices have pervaded virtually all aspects of modern life. From cell phones to equipment for manufacturing airplanes, integrated circuit devices improve processes and machines that are often take for granted.

The demands for electronic devices with integrated circuits increasingly require more functions with faster response in reduced dimensions and at lower prices. These high performance devices often demand all of lighter, faster, smaller, multi-functional, highly reliable, and lower cost.

In efforts to meet such requirements, improvements have been attempted in many aspects of electronic product development such as producing smaller and less expensive semiconductor chips. Unfortunately, this development is still not enough to satisfy the demands. Every aspect including packaging can contribute.

A commonly used integrated circuit or semiconductor device methodology for packaging uses a substrate for the semiconductor chips. The substrate or “board” provides a connection pattern of input and output elements such as contacts, leads, or other electrodes connecting the integrated circuit.

Numerous technologies have been developed to meet these requirements. Some research and development focused on new package technologies while others focused on improving existing and mature package technologies. Research and development in package technologies may include a seemingly endless number of different approaches.

One proven way to reduce cost is to use package technologies with existing manufacturing methods and equipments. Paradoxically, the reuse of existing manufacturing processes does not typically result in the reduction of package size. Existing packaging technologies struggle to cost effectively meet demands of today's integrated circuit packages.

Of course, the requirement of additional material including the substrate undesirably increases the thickness and cost of fabricating the package. Moreover, the use of an additional substrate material may undesirably increase the manufacturing cycle time, which can also increase cost.

Despite the advantages of recent developments in semiconductor fabrication and packaging techniques, there is a continuing need for improving electronic device size, performance, reliability, and manufacturing.

Thus, a need still remains for an integrated circuit package system with improved manufacturing processes and materials.

In view of the ever-increasing commercial competitive pressures, along with growing consumer expectations and the diminishing opportunities for meaningful product differentiation in the marketplace, it is critical that answers be found for these problems.

Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system that includes: providing a die attach pad; forming a package contact pad adjacent the die attach pad; attaching an integrated circuit over the die attach pad; attaching a die connector to the integrated circuit and the package contact pad; and forming an encapsulant over the die connector and the integrated circuit, the encapsulant having an encapsulant edge from a sawless singulation process.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package system taken along line 1-1 of FIG. 2 in a first embodiment of the present invention;

FIG. 2 is a bottom plan view of the integrated circuit package system;

FIG. 3 is a side view of the integrated circuit package system in a carrier phase;

FIG. 4 is the structure of FIG. 3 in an attachment phase;

FIG. 5 is the structure of FIG. 4 in an encapsulation phase;

FIG. 6 the structure of FIG. 5 in another carrier phase;

FIG. 7 is the structure of FIG. 6 in an etch-out phase;

FIG. 8 is an integrated circuit package system in an encapsulation phase of a second embodiment of the present invention;

FIG. 9 is the structure of FIG. 8 in a mold phase;

FIG. 10 is a cross-section view of an integrated circuit package system taken along line 10-10 of FIG. 11 in a dispense phase of a third embodiment of the present invention;

FIG. 11 is a top plan view of the structure of FIG. 10; and

FIG. 12 is a flow chart of an integrated circuit package system for manufacturing the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGS.

Where multiple embodiments are disclosed and described, having some features in common, for clarity and ease of illustration, description, and comprehension thereof, similar and like features one to another will ordinarily be described with like reference numerals. The embodiments may be numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the invention, regardless of its orientation. The term “vertical” refers to a direction perpendicular to the horizontal as just defined. Terms, such as “on”, “above”, “below”, “bottom”, “top”, “side” (as in “sidewall”), “upward”, “downward”, “higher”, “lower”, “upper”, “over”, and “under”, are defined with respect to the horizontal plane.

The term “on” as used herein means and refers to direct contact among elements. The term “processing” as used herein includes deposition of material, patterning, exposure, development, etching, cleaning, and/or removal of the material or trimming as required in forming a described structure. The term “system” as used herein means and refers to the method and to the apparatus of the present invention in accordance with the context in which the term is used.

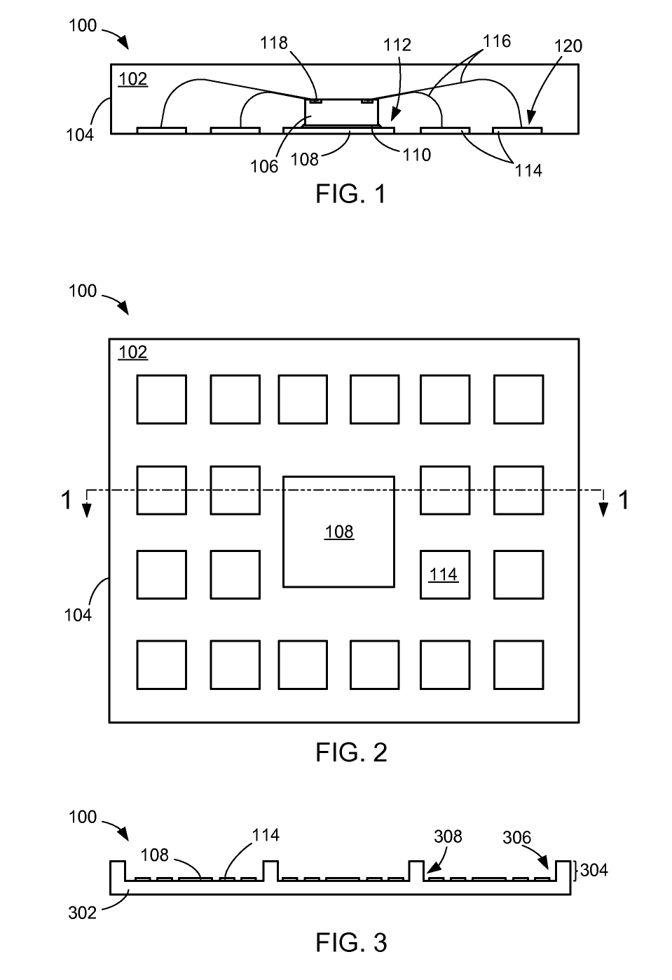

Referring now to FIG. 1, therein is shown a cross-sectional view of an integrated circuit package system 100 taken along line 1-1 of FIG. 2 in a first embodiment of the present invention. The integrated circuit package system 100 preferably includes an encapsulant 102 having an encapsulant edge 104.

The encapsulant edge 104 can include dimensions and surface characteristics resulting from a sawless singulation process such as a removal or etch process. The encapsulant edge 104 can be formed having a consistent surface without tool marks and dimensions predetermined by a form such as a mold or carrier without destructive singulation.

The encapsulant 102 with the encapsulant edge 104 can be formed without sawing or cutting processes resulting in eliminated blade costs, reduced deionized water, or reduced waste water. Processes such as the etch process can eliminate sawing or cutting for singulation or separation of each of the integrated circuit package system 100.

An integrated circuit 106 can be attached or mounted over a die attach pad 108 with an attach layer 110. The attach layer 110 can provide adhesion, conductivity, or insulation on a mounting surface 112 of the die attach pad 108. The die attach pad 108 can be formed of conductive material similar or different from package contact pads 114.

The integrated circuit 106 can be electrically connected to the package contact pads 114 by die connectors 116. Integrated circuit pads 118 of the integrated circuit 106 can provide an electrically conductive region for connecting the die connectors 116 to a connection surface 120 of the package contact pads 114. The integrated circuit pads 118 can be bond pads or other conductive region.

The package contact pads 114 can optionally be formed in one or more rows adjacent an outer perimeter of the die attach pad 108. The package contact pads 114 formed in a rows near the die attach pad 108 can provide shorter lengths of the die connectors 116 and thereby improved signal integrity for signal levels.

The encapsulant 102 can cover or protect the die connectors 116, the integrated circuit 106, the die attach pad 108, or the package contact pads 114. The encapsulant 102 includes the encapsulant edge 104 preferable formed near a perimeter of the die connectors 116, the integrated circuit 106, the die attach pad 108, or the package contact pads 114.

It has been unexpectedly discovered that the present invention with the encapsulant edge 104 having dimensions and characteristics of a sawless singulation process improves manufacturing production including costs. The improved production can include eliminated blade costs, reduced equipment maintenance, reduced deionized water, reduced waste water, higher quality control, or increased utilization of the etch-out process.

Referring now to FIG. 2, therein is shown a bottom plan view of the integrated circuit package system 100. The encapsulant 102 having the encapsulant edge 104 can provide the die attach pad 108 and the package contact pads 114 substantially exposed.

The integrated circuit 106 of FIG. 1 can be mounted over the die attach pad 108 and electrically connected to the package contact pads 114. The package contact pads 114 can be formed near a perimeter of the die attach pad 108. The die attach pad 108 can optionally be connected to an electrical level such as ground and the package contact pads 114 can optionally be connected to an electrical level or an electrical signal.

For illustrative purposes, the package contact pads 114 are shown in a four by six array although it is understood that the package contact pads 114 may be different. Any number of the package contact pads 114 may be used and the package contact pads 114 may be formed in any configuration.

Referring now to FIG. 3, therein is shown a side view of the integrated circuit package system 100 in a carrier phase. The integrated circuit package system 100 preferably includes the die attach pad 108 and the package contact pads 114 formed over a base carrier 302 such as carrier strip.

The base carrier 302 can preferably be formed of a material such as copper, other metals, or any substance that can be removed by sawless singulation such as a removal or etching process. A removal process can remove the base carrier 302 and provide the die attach pad 108 and the package contact pads 114 substantially intact.

The base carrier 302 can include base protrusions 304 extending from a side including the die attach pad 108 and the package contact pads 114. The base protrusions 304 can form a base recess 306 for the integrated circuit 106 of FIG. 1. The base carrier 302 and the base protrusions 304 can be formed of the same or different material.

The base protrusions 304 can include a protrusion surface 308 facing the base recess 306. The protrusion surface 308 can provide structural boundaries for the encapsulant 102 of FIG. 1 thereby providing a forming surface for conformal materials. Conformal materials can conform or mirror the protrusion surface 308.

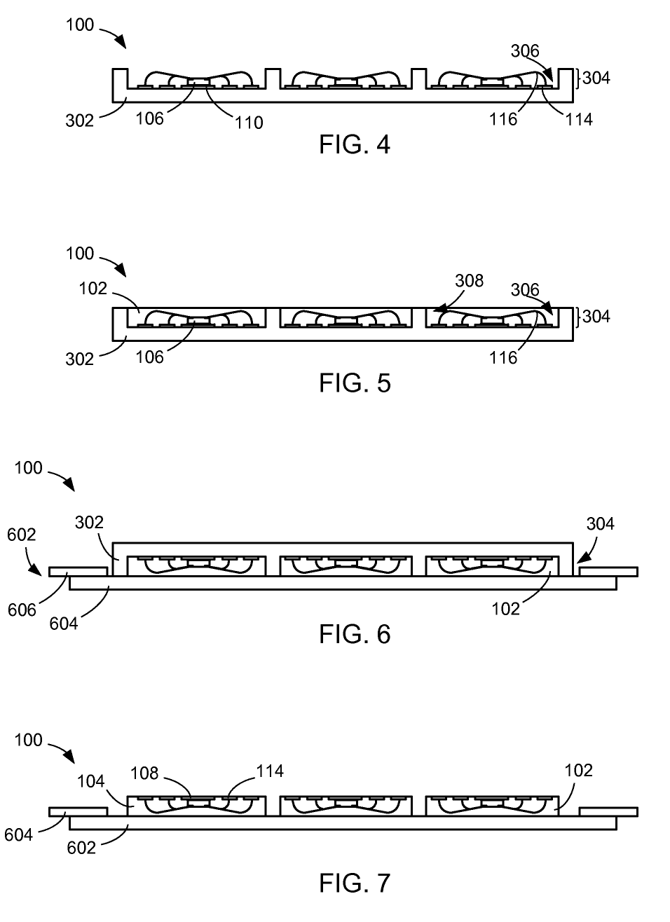

Referring now to FIG. 4, therein is shown the structure of FIG. 3 in an attachment phase. The integrated circuit package system 100 preferably includes the integrated circuit 106 mounted on the attach layer 110 on the die attach pad 108 and at least partially within the base recess 306.

The die connectors 116 can electrically connect the integrated circuit 106 and the package contact pads 114 over the base carrier 302. The die connectors 116 can be electrically connected to one or more rows of the package contact pads 114 adjacent the base protrusions 304 and at least partially within the base recess 306.

Referring now to FIG. 5, therein is shown the structure of FIG. 4 in an encapsulation phase. The integrated circuit package system 100 preferably includes the encapsulant 102 at least partially in the base recess 306. The encapsulant 102 can be formed on the base protrusions 304 resulting in a surface that substantially mirrors the protrusion surface 308.

The encapsulant 102 can cover and protect the integrated circuit 106, the die connectors 116, a portion of the die attach pad 108, and a portion of the package contact pads 114. The base recess 306 formed by the base carrier 302 with the base protrusions 304 can provide dimensions and surface characteristics for the encapsulant 102.

Referring now to FIG. 6, therein is shown the structure of FIG. 5 in another carrier phase. The integrated circuit package system 100 preferably includes a removal carrier 602. The removal carrier 602 can optionally include a removal carrier tape 604 or a removal carrier frame 606.

A side of the structure of FIG. 5 opposite the base carrier 302 of FIG. 5 can be mounted over the removal carrier 602. The base protrusions 304 and the encapsulant 102 can be mounted over the removal carrier 602. The structure of FIG. 5 can optionally be attached to the removal carrier tape 604 and adjacent the removal carrier frame 606.

Referring now to FIG. 7, therein is shown the structure of FIG. 6 in an etch-out phase. The integrated circuit package system 100 preferably includes the die attach pad 108, the package contact pads 114, and a portion of the encapsulant 102 substantially exposed.

A removal process can provide the encapsulant edge 104 with a consistent surface without tool marks and dimensions predetermined by a form such as a mold or carrier without destructive singulation. Dimensions and surface characteristics can result from a sawless singulation process such as a removal or etch process.

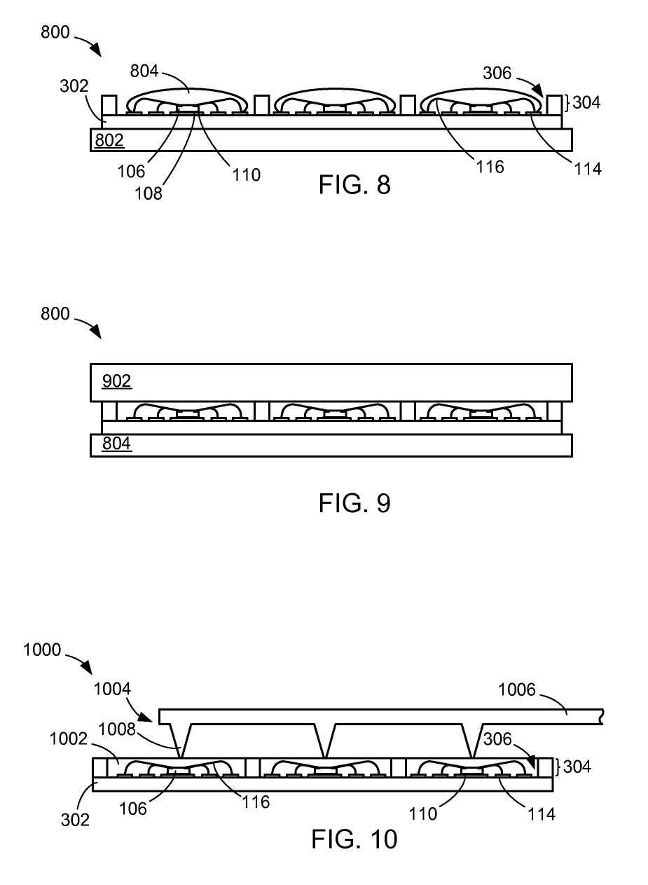

Referring now to FIG. 8, therein is shown an integrated circuit package system 800 in an encapsulation phase of a second embodiment of the present invention. The integrated circuit package system 800 preferably includes a bottom mold 802 such as a mold clamp or mold chase. A side of the structure of FIG. 4 opposite the base recess 306 can be attached or mounted over the bottom mold 802.

An encapsulant 804 such as a liquid or powder compound can be applied in the base recess 306 of the base carrier 302 with the base protrusions 304. The encapsulant 804 can at least partially cover the integrated circuit 106, the die connectors 116, a portion of the die attach pad 108, and a portion of the package contact pads 114.

The encapsulant 804 can be formed with processes such as liquid epoxy molding or compression molding particularly for wire sweep sensitive applications such as multiple row, high I/O count, long wire span, or bump chip carriers (BCC). The encapsulant 804 can provide molding of thin packages without voids or wire sweep.

Referring now to FIG. 9, therein is shown the structure of FIG. 8 in a mold phase. The integrated circuit package system 800 preferably includes a top mold 902 such as a mold clamp or mold chase. The top mold 902 can be mounted on a side opposite the bottom mold 802.

The top mold 902 can provide pressure or a reduced area for the encapsulant 804 wherein the encapsulant 804 conforms to a region formed by the base recess 306 and the top mold 902. The encapsulant 804 can cover and protect the integrated circuit 106, the die connectors 116, a portion of the die attach pad 108, and a portion of the package contact pads 114.

The base recess 306 formed by the base carrier 302 with the base protrusions 304 can provide dimensions and surface characteristics for the encapsulant 804 resulting from a sawless singulation process such as a removal or etches process. The encapsulant edge 104 can be formed having a consistent surface without tool marks and dimensions predetermined by a form such as a mold or carrier without destructive singulation.

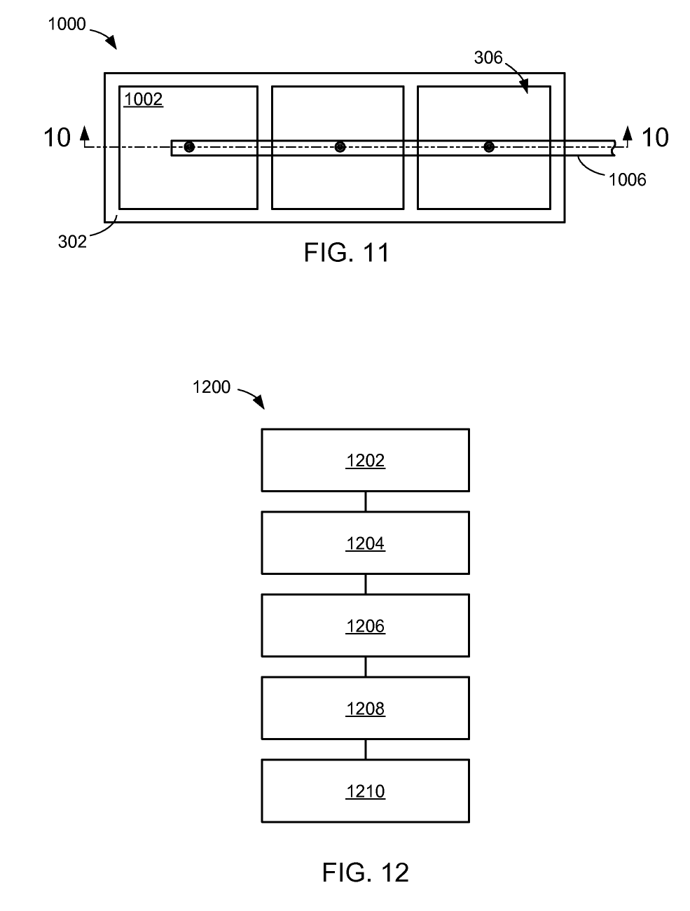

Referring now to FIG. 10, therein is shown a cross-section view of an integrated circuit package system 1000 taken along line 10-10 of FIG. 11 in a dispense phase of a third embodiment of the present invention. The integrated circuit package system 1000 preferably includes an encapsulant 1002 such as a mold material.

The encapsulant 1002 can be applied with a dispensing device 1004. The dispensing device 1004 can include a mold runner 1006 or a gate 1008 such as a top gate. The mold runner 1006 can provide the encapsulant 1002 through the gate 1008 and at least partially within the base recess 306 formed by the base carrier 302 with the base protrusions 304.

The encapsulant 1002 can cover and protect the integrated circuit 106, the die connectors 116, a portion of the die attach pad 108, and a portion of the package contact pads 114. The dispensing device 1004 can provide narrow clearances between unit cavities for devices or components that cannot be encapsulated with side gate processes.

Referring now to FIG. 11, therein is shown a top plan view of the structure of FIG. 10. The integrated circuit package system 1000 preferably includes the dispensing device 1004 optionally including the mold runner 1006 or the gate 1008.

The encapsulant 1002 can be applied with the dispensing device 1004 with a process such as a top gated molding process or a transfer molding process. The encapsulant 1002 can be applied at least partially in the base recess 306 of the base carrier 302.

The dispensing device 1004 can apply the encapsulant 1002 to cover and protect package components as well as provide narrow clearances between unit cavities for devices or components that cannot be encapsulated with side gate processes.

Referring now to FIG. 12, therein is shown a flow chart of an integrated circuit package system 1200 for manufacturing the integrated circuit package system 100 in an embodiment of the present invention. The system 1200 includes providing a die attach pad in a block 1202; forming a package contact pad adjacent the die attach pad in a block 1204; attaching an integrated circuit over the die attach pad in a block 1206; attaching a die connector to the integrated circuit and the package contact pad in a block 1208; and forming an encapsulant over the die connector and the integrated circuit, the encapsulant having an encapsulant edge from a sawless singulation process in a block 1210.

In greater detail, a system to provide the method and apparatus of the integrated circuit package system 100, in an embodiment of the present invention, is performed as follows:
1. Providing a redistribution network having a re-routing film.
2. Attaching a device over the redistribution network.
3. Attaching a base connector to the base device and the re-routing film.
4. Attaching a package connector over a side of the redistribution network opposite the base device.
5. Applying an encapsulant over the base device, the base connector, and the redistribution network.

Thus, it has been discovered that the integrated circuit package system method and apparatus of the present invention furnish important and heretofore unknown and unavailable solutions, capabilities, and functional aspects.

The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description.

Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit package system comprising:
providing a die attach pad;
forming a package contact pad adjacent the die attach pad;
attaching an integrated circuit over the die attach pad;
attaching a die connector to the integrated circuit and the package contact pad; and
forming an encapsulant over the die connector and the integrated circuit, the encapsulant having an encapsulant edge from a sawless singulation process.

2. The system as claimed in claim 1 wherein forming the encapsulant includes forming the encapsulant edge substantially mirroring a base protrusion.

3. The system as claimed in claim 1 wherein forming the encapsulant includes forming the encapsulant edge having dimensions predetermined by a base carrier.

4. The system as claimed in claim 1 wherein forming the encapsulant includes forming the encapsulant with a compression molding process.

5. The system as claimed in claim 1 wherein forming the encapsulant includes forming the encapsulant with a top gated molding process.

6. An integrated circuit package system comprising:
providing a die attach pad having a mounting surface;
forming a package contact pad having a connection surface adjacent the die attach pad;
attaching an integrated circuit having an integrated circuit pad over the die attach pad;
attaching a die connector to the integrated circuit pads and the connection surface; and
forming an encapsulant over the die connector and the integrated circuit, the encapsulant having an encapsulant edge with dimensions and surface characteristics from a sawless singulation process.

7. The system as claimed in claim 6 wherein forming the encapsulant includes forming the encapsulant edge substantially mirroring a protrusion surface of a base protrusion removed by a sawless singulation process.

8. The system as claimed in claim 6 wherein forming the encapsulant includes forming the encapsulant edge having dimensions predetermined by a base carrier removed by a sawless singulation process.

9. The system as claimed in claim 6 wherein forming the encapsulant includes forming the encapsulant with a liquid epoxy molding process and a compression molding process.

10. The system as claimed in claim 6 wherein forming the encapsulant includes forming the encapsulant with a transfer molding process.

11. An integrated circuit package system comprising:
a die attach pad;
a package contact pad adjacent the die attach pad;
an integrated circuit over the die attach pad;
a die connector to the integrated circuit and the package contact pad; and
an encapsulant over the die connector and the integrated circuit, the encapsulant having an encapsulant edge characteristic of a sawless singulation process.

12. The system as claimed in claim 11 wherein the encapsulant includes the encapsulant edge substantially mirroring a base protrusion.

13. The system as claimed in claim 11 wherein the encapsulant includes the encapsulant edge having dimensions predetermined by a base carrier.

14. The system as claimed in claim 11 wherein the encapsulant includes the encapsulant with characteristics of a compression molding process.

15. The system as claimed in claim 11 wherein the encapsulant includes the encapsulant with characteristics of a top gated molding process.

16. The system as claimed in claim 11 wherein:
the die attach pad has a mounting surface;
the package contact pad has a connection surface adjacent the die attach pad;
the integrated circuit has an integrated circuit pad over the die attach pad;
the die connector is attached to the integrated circuit pads and the connection surface; and
the encapsulant is over the die connector and the integrated circuit, the encapsulant having the encapsulant edge with dimensions and surface characteristics from a sawless singulation process.

17. The system as claimed in claim 16 wherein the encapsulant includes the encapsulant edge substantially mirroring a protrusion surface of a base protrusion removed by a sawless singulation process.

18. The system as claimed in claim 16 wherein the encapsulant includes the encapsulant edge having dimensions predetermined by a base carrier removed by a sawless singulation process.

19. The system as claimed in claim 16 wherein the encapsulant includes the encapsulant having characteristics of a liquid epoxy molding process and a compression molding process.

20. The system as claimed in claim 16 wherein the encapsulant includes the encapsulant having characteristics of a transfer molding process.
